(19) United States
(12) Patent Application Publication
(10) Pub. No.: US 2020/0395731 A1
(43) Pub. Date: Dec. 17, 2020

(54) Insulated Laser Coolers

(71) Applicant: Trumpf Photonics Inc., Cranbury, NJ (US)

(72) Inventors: Thilo Vethake, Cranbury, NJ (US); Stefan Heinemann, Hightstown, NJ (US)

(21) Appl. No.: 16/437,025

(22) Filed: Jun. 11, 2019

(51) Int. Cl. H01S 5/024

(52) U.S. Cl. CPC H01S 5/02469; H01S 5/02484; H01S 5/02423

(57) ABSTRACT

A laser diode heat sink including: a main body portion formed of metal; an electrically insulating layer on a principal surface of the main body portion, in which an interface between the main body portion and the electrically insulating layer includes multiple interlocking structures; and a metal mounting layer for mounting a laser diode on the electrically insulating layer.

### TECHNICAL FIELD

The present disclosure relates to insulated laser coolers.

### BACKGROUND

High-powered semiconductor laser diodes are cooled to keep the junction temperature and carrier leakage low and reliability high. Laser diodes can be mounted to electrically insulated coolers, which helps reduce thermal impedance.

### SUMMARY

In general, in some aspects, the subject matter of the present disclosure is embodied in laser diode heat sinks that include: a main body portion formed of metal; an electrically insulating layer on a principal surface of the main body portion, in which an interface between the main body portion and the electrically insulating layer includes multiple interlocking structures; and a metal mounting layer for mounting a laser diode on the electrically insulating layer.

Implementations of the heat sinks may include one or more of the following features. For example, in some implementations, an effective coefficient of thermal expansion of the laser diode heat sink is approximately matched to a coefficient of thermal expansion of the laser diode.

In some implementations, an effective coefficient of thermal expansion of the laser diode heat sink is between about 5.5*10⁻⁶/K and about 6.5*10⁻⁶/K.

In some implementations, the interlocking structures include multiple protrusions arranged in a periodic array. A pitch between adjacent protrusions in the periodic array may be greater than about 1 micron. A distance between adjacent protrusions in the periodic array may be greater than about 0.5 micron.

In some implementations, the protrusions include multiple elongated ridges.

In some implementations, the protrusions include multiple nodules.

In some implementations, a thickness of the multiple protrusions is between approximately 1 micron to approximately 50 microns.

In some implementations, a thickness of the electrical insulating layer is between approximately 1 micron and approximately 50 microns.

In some implementations, the electrical insulating layer includes a diamond layer.

In some implementations, a thickness of the mounting layer is between approximately 100 microns to approximately 500 microns.

In some implementations, the multiple interlocking structures include multiple depressions defined by the principal surface of the main body portion, and wherein the mounting layer fills the multiple depressions.

In some implementations, the main body portion include multiple integrated fluid channels.

In some other aspects, the subject matter of the present disclosure is embodied in methods that include: providing a main body portion formed of metal; forming multiple protrusions on or multiple openings in a principal surface of the main body portion; forming an electrically insulating layer on the principal surface so as to cover the multiple protrusions or multiple openings and form interlocking structures with the multiple protrusions or with the multiple openings; and forming a laser diode mounting layer on the electrically insulating layer.

Implementations of the methods may include one or more of the following features. For example, in some implementations, forming the multiple openings in the principal surface of the main body portion includes performing at least one of mechanically milling, chemically etching or laser scribing predefined regions of the principal surface.

In some implementations, forming the multiple protrusions on the principal surface of the main body portion includes: depositing a layer of metal on the principal surface to form a deposited metal layer; and patterning the deposited metal layer to form the multiple protrusions.

In some implementations, forming the electrically insulating layer includes forming a diamond film on the principal surface.

In some implementations, forming the laser diode mounting layer includes electroplating the laser diode mounting layer on the electrically insulating layer.

In some implementations, forming the laser diode mounting layer includes soldering the laser diode mounting layer to the electrically insulating layer.

Implementations of the subject matter of the present disclosure may include one or more of the following advantages. For example, in some implementations, the interlocking structures help reduce the effective coefficient of thermal expansion of the heat sink to lead to a reduction in the internally generated stresses/forces caused by heating during operation of a laser diode. This reduction in thermally induced stress can further reduce the occurrence of delamination, in particular with an insulator such as diamond that has a high thermal conductivity and enables improvements in heat sink efficiency and laser diode reliability.

The details of one or more embodiments of the invention are set forth in the accompanying drawings and the description below. Other features and advantages will be apparent from the description, drawings, and claims.

### BRIEF DESCRIPTION OF THE DRAWINGS

FIG. 1 is a schematic that illustrates an example of an electrically insulated laser diode cooler.

FIGS. 2A-2F are schematics that illustrate an example process for fabricating an electrically insulated laser diode cooler.

FIG. 2G is a schematic that illustrates a side view of an example laser diode cooler that includes a first set of interlocking structures formed using raised features at the interface between layer and main body portion, and a second set of interlocking structures formed using raised features at the interface between layer and mounting layer.

FIG. 3 is a schematic that illustrates a top view of an insulating layer of an example electrically insulated laser diode cooler. FIG. 4 is a schematic that illustrates a top view of an insulating layer of an example electrically insulated laser diode cooler.

### DETAILED DESCRIPTION

To keep junction temperature, carrier leakage low and reliability high, high-powered semiconductor laser diodes may be cooled by mounting the laser diodes to a heat sinks including, e.g., electrically insulated coolers. An example of an electrically insulated cooler to which laser diodes can be mounted is the ILASCO diode cooler, which is fabricated from a stack of thin copper sheets sandwiched between two electrically insulating layers. The individual stacked copper sheets included integrated coolant passages through which a coolant is provided. An electrically conductive mounting pad (e.g., a layer of copper) is provided on at least one of the electrically insulating layers. The laser diode then may be mounted directly to the electrically conductive mounting pad. For example, the p-side contact of the semiconductor laser diode may be soldered to the electrically conductive mounting pad. The insulating layers are provided to prevent electro-corrosion of the metallic cooling structure and are generally formed from material having high thermal conductivity (e.g., aluminum nitride) to maintain cooling efficiency of the heat sink.

Using electrically insulating materials with even higher thermal conductivity than aluminum nitride can further reduce thermal impedance, leading to improvements in cooling efficiency of the laser diode cooler and, in some cases, enabling an increase in laser diode output power. A material that exhibits high thermal conductivity and that exhibits desirable electrically insulating properties is diamond. For example, chemical vapor deposited diamond may have a thermal conductivity of about 2000 W/m*K and an electrical resistivity of greater than 10¹⁴ ohm-cm. A complication of using diamond layers as the insulating layer in a laser diode cooler is that it may delaminate due to a mismatch in coefficient of thermal expansion between the diamond and the electrically conductive material (e.g., the copper layers used to form the integrated coolant passages and the mounting pad). Moreover, diamond also exhibits a much greater stiffness than most metals, which further contributes to delamination when the different materials are heated and expand at different rates.

The present disclosure relates to laser diode heat sinks, also referred to herein as laser diode coolers, that are structured so that delamination of the electrically insulating layer may be reduced or prevented. In particular, one or more interfaces between the electrically insulating layer and the adjacent electrically conductive portions of the laser diode cooler are structured to enhance the adhesion between the different materials. Material may be locally removed and/or locally added to the interfaces to create a series of interlocking structures that improve the adhesion between materials. The interlocking structures may be formed to include, e.g. protrusions such as ridges, nodules, as well as voids such as dimples and grooves. In addition, in some cases, the electrically insulating layer, the mounting layer, and/or the cooler with the integrated coolant passages may be configured to have a combined coefficient of thermal expansion that matches a coefficient of thermal expansion of the laser diode to further improve reliable operation of the laser diode and reduce or prevent delamination.

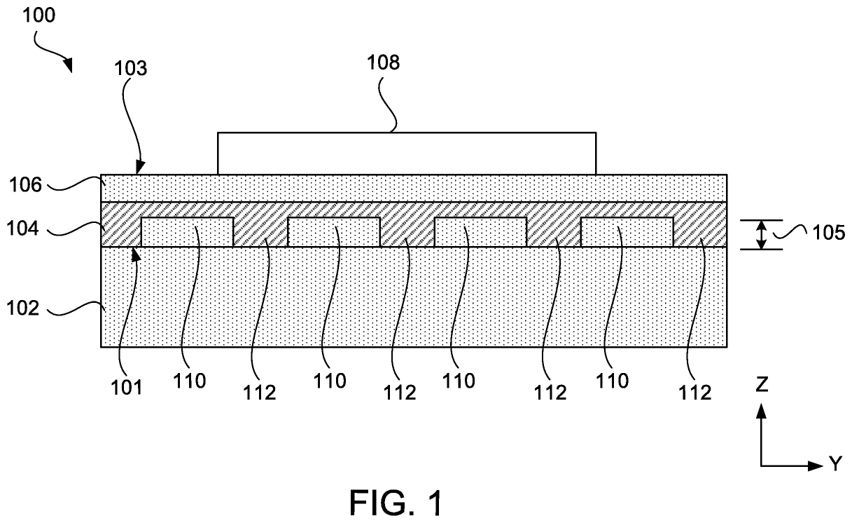

FIG. 1 is a schematic that illustrates an example of an electrically insulated laser diode cooler 100 according to the present disclosure. The laser diode cooler 100 transfers heat generated from a laser diode during operation of the diode and thus maintains the diode at a stable temperature. As shown in FIG. 1, the laser diode cooler 100 includes a main body portion 102. The main body portion 102 includes a heat sink. For example, the main body portion 102 may be formed from a metal block, such as copper, having one or more integrated coolant passages through which a coolant is provided during operation of the laser diode. In some cases, the metal block is formed from a stack of copper plates that are bonded together, in which each plate is constructed to defined a different part of the integrated coolant passage.

An electrically insulating layer 104 is provided on a principle surface 101 of the main body portion 102. The electrically insulating layer 104 inhibits or prevents electro-corrosion of the metallic cooling structure and has a high thermal conductivity to reduce the overall thermal impedance of the laser diode cooler 100. A laser diode mounting layer 106 is provided on a surface of the electrically insulating layer 104. The laser diode mounting layer 106 includes an electrically conductive thin or thick film, such as a copper film, and provides a path through which current can be provided to a laser diode. For example, as shown in FIG. 1, a laser diode 108 is mounted to a principle surface 103 of the mounting layer 106. A bottom surface of the laser diode 108 may include a diode contact, e.g., a p-type or n-type contact, that is soldered to the laser diode mounting layer 106. The mounting layer 106 also may have a high thermal conductivity to maintain a low thermal impedance of the cooler 100, such that the main body portion 102, insulating layer 104 and mounting layer 106 together effectively serve as a heat sink for the laser diode. The types of laser diodes that can be mounted to the laser diode cooler 100 include, e.g., a semiconductor laser diodes such as a vertical cavity surface emitting lasers, quantum well lasers, distributed feedback lasers, among other types of laser diodes.

The electrically insulating layer 104 is a material that has high thermal conductivity and high electrical resistivity. For example, the electrically insulating layer 104 may be formed from diamond. Other electrically insulating materials may be used instead, including, but not limited to, SiC, AlN, SiN, BeO, or AlO. To enhance the adhesion of the electrically insulating layer 104 to the main body portion 102 and to inhibit delamination, the interface between the main body portion 102 and the electrically insulating layer 104 is configured to include multiple interlocking structures. Introducing the multiple interlocking structures increases the contact surface area between the insulating layer 104 and the main body portion 102 and provides a counter force to the mechanical force generated by the different thermal expansion rates of the insulator material and the electrical conductor material used for the main body portion 102. The interlocking structures at the interface between the electrically insulating layer 104 and the main body portion 104 may include, e.g., raised features 110 that protrude from the principle surface 101 of the main body portion 102. The interlocking structures may also include portions of the electrically insulating layer 104 that fill the regions 112 between the raised features 110. For example, the raised features 110 may include protrusions, ridges, nodules, rings, or other projections from the principle surface 101 of the main body portion 102, in which the electrically insulating layer 104 fills the space between the raised features 110. Alternatively, or in addition, the regions 112 may be voids or depressions where the main body portion 102 has been removed. The raised features 110 between the regions 112 then may correspond to parts of the main body portion 102 that have not been removed. For example, the regions 112 may include dimples, grooves, vias, holes, indentations, or channels formed in the main body portion 102, in which the electrically insulating layer 104 fills such openings.

The raised features 110 may have a thickness 105 that ranges from hundreds of nanometers up to several tens of micrometers including, e.g., 50 microns, relative to the principle surface 101 of the main body portion 102. For example, the thickness 105 of the raised features may be greater than about 100 nm, greater than about 500 nm, greater than about 1 micron, greater than about 2 microns, greater than about 4 microns, greater than about 5 microns, greater than about 10 microns, greater than about 20 microns, greater than about 25 microns, greater than about 30 microns, greater than about 40 microns, greater than about 50 microns, or greater than about 75 microns. A thickness of the electrically insulating layer 104 is at least as thick as the raised features 110, though adhesion may be improved in implementations where the insulating layer thickness is greater than the thickness 105 of the raised features 110. For instance, the thickness of the electrically insulating layer 104 may be 1×, 2×, 3×, 4×, 5×, or 10× as thick as the thickness 105. As examples, the layer 104 may have a thickness of 200 nm or greater, 500 nm or greater, 1 micron or greater, 5 microns or greater, 10 microns or greater, 25 microns or greater, or up to about 50 microns.

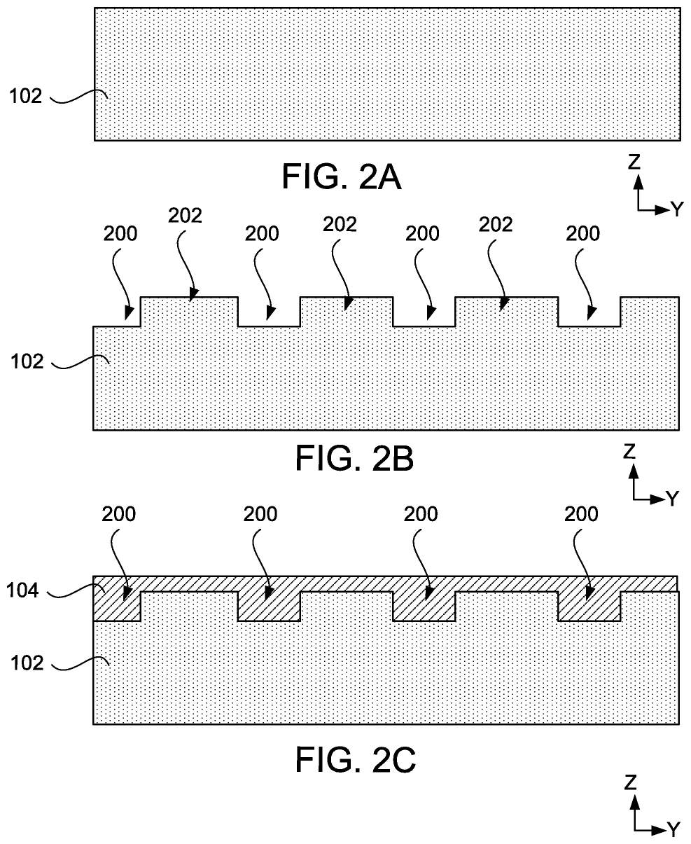

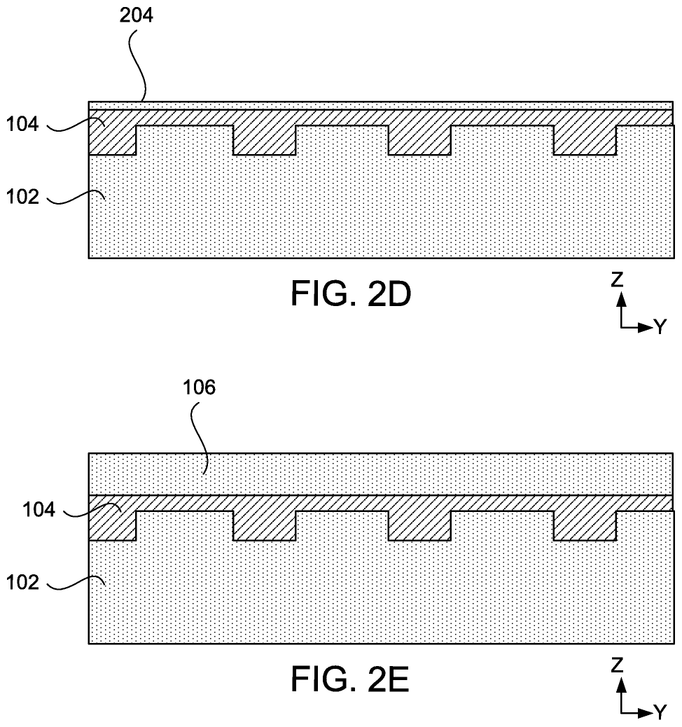

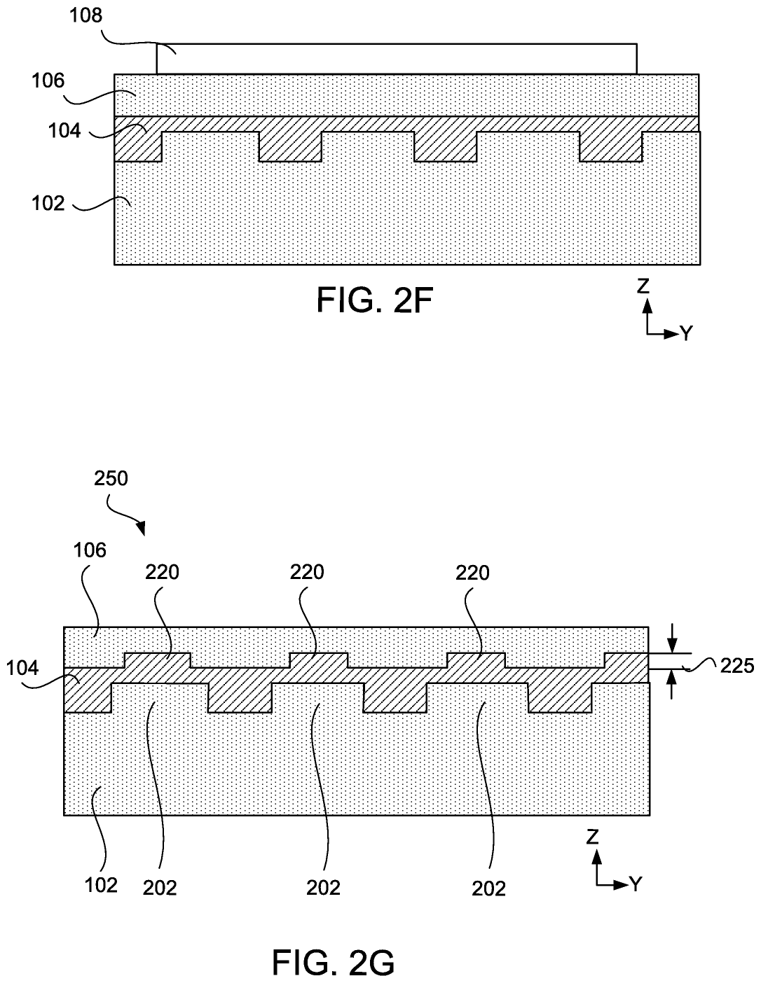

FIGS. 2A-2F are schematics that illustrate an example process for fabricating an electrically insulated laser diode cooler, such as the laser diode cooler 100. As shown in FIG. 2A, a main body portion 102 is first provided. As explained herein, the main body portion 102 may include a heat sink formed from a high thermal conductivity material (e.g., greater than about 200 W/mK), such as copper block or a stack of copper plates bonded together. Other materials for the main body portion 102 may include, e.g., gold or silver. The main body portion 102 may include one or more internally integrated coolant passages through which a coolant may be provided. As an example, the main body portion 102 may be between about 0.1 mm to about 5 mm thick, have a width between about 1 mm to about 50 mm, and have a length of between about 3 mm to about 120 mm. A surface area of a side of the main body portion 102 on which a laser diode will be fixed should be large enough to match the surface area of the face of the laser diode that will be mounted. In FIG. 2B, multiple raised features 202 are formed on the main body portion 102. The raised features 202 may be formed in multiple different ways. For example, in some implementations, the raised features 202 may be formed by creating openings or voids 200 in the surface of the main body portion 102. The openings or voids 200 may be created using material removal processes such as mechanical milling, chemical etching, ion milling, or laser scribing, among other methods. The regions of main body portion 102 between the openings or voids 200 that are not removed remain as the raised features 202. For example, in some implementations, the openings or voids 200 may be formed by using a combination of photolithography to define where the voids 200 are located and chemical etching to remove material from exposed regions of the main body portion 102. The openings or voids 200 may have a predetermined pattern. For example, as disclosed herein, the openings or voids 200 may be formed as dimples, grooves, vias, holes, indentations, or channels. The openings or voids 200 may be arranged in an ordered array or other predetermined pattern. The depth of the openings or voids 200 may be in the range of thicknesses disclosed above for the raised features.

In other implementations, the raised features 202 are formed through an additive process rather than a subtractive process. For example, the raised features 202 may be formed using a physical deposition process, such as sputtering, electron beam deposition, physical vapor deposition, or through an electrolytic process such as electroplating. The material that is formed on the surface of the main body portion 102 to provide the raised features 202 may be the same as, or different than, the material that forms the main body portion 102. For example, the material that forms the raised features 202 may include copper, silver or gold, among others. To reduce delamination, the material used to form the raised features 202 can have a coefficient of thermal expansion that is close to or the same as the coefficient of thermal expansion of the material used to form the main body portion 102. The raised features 202 may be arranged in a predetermined pattern including, e.g., an ordered array having a predefined period between adjacent raised features.

After forming the raised features 202, the electrically insulating layer 104 is formed on the surface of main body portion 102 so as to cover the raised features 202, as shown in FIG. 2C. As disclosed herein, the electrically insulating layer 104 may include, e.g., a material having high thermal conductivity (e.g., greater than about 200 W/m*K) and a high electrical resistivity (e.g., greater than about 10¹⁴ ohms-cm) such as diamond or aluminum nitride. Forming the electrically insulating layer 104 may include, e.g., depositing the layer 104 using a physical vapor deposition process such as chemical vapor deposition, plasma enhanced chemical vapor deposition, magnetron sputtering, or e-beam evaporation, among other techniques. The layer 104 is deposited to a thickness that is sufficient to cover at least the height of the raised features 202. For example, as explained herein, the layer 104 may be deposited to a thickness between about 2× and about 10× the thickness of the raised features 202. The deposition process results in the insulating layer 104 filling the regions 200 between the raised features and this forming the interlocking structures. In some implementations, after the electrically insulating layer 104 is deposited over the raised features 202, the exposed surface of the insulating layer 104 may be polished and/or exposed to a brief etch process (e.g., a reactive ion etch). Polishing and/or etching the surface of the insulating layer 104 may improve adhesion between the layer 104 and the to-be-formed mounting layer by removing particles and/or contaminants that may otherwise lessen the strength of the bond between the electrically insulating layer 104 and the mounting layer.

In FIGS. 2D-2E, the mounting layer 106 is formed on the exposed surface of the electrically insulating layer 104. The mounting layer 106 includes a material having high electrical conductivity to function as an electrical contact for the laser diode. Additionally, to maintain satisfactory heat transfer from the laser diode to the main body portion 102, the mounting layer 106 material have high thermal conductivity. Examples of materials that may be suitable for the mounting layer 106 include copper, silver or gold, among others.

The mounting layer 106 may be formed using multiple different techniques. For example, in some implementations, the mounting layer 106 may be formed using an electrolytic process such as electrolysis. Electrolysis may include, e.g., first forming a seed layer 204 on the insulating layer 104 as shown in FIG. 2D. The seed layer 204 may be deposited using a physical vapor deposition process, such as thermal evaporation or e-beam evaporation, sputtering, or chemical vapor deposition. The seed layer 204 may have a thickness in the range of, e.g., about 10 nm to about 200 nm. Following formation of the seed layer 204, the rest of the mounting layer 106 may be formed using electrolysis, as shown in FIG. 2E. The final thickness of the mounting layer 106 may be in the range of, e.g., about 100 microns to about 500 microns.

Techniques other than electrolytic techniques also may be used to form the mounting layer 106. For example, in some implementations, the mounting layer may be attached to the electrically insulating layer 104 using a bonding process, such as thermos-compression bonding. Thermo-compression bonding entails applying heat and pressure to the mating surface by a bonding tool. For instance, a separate copper plate having the desired thickness may be separately provided and then bonded to the electrically insulating layer using thermos-compression techniques. To reduce defects that may lead to delamination, a surface of the plate to be bonded may be cleaned by one or more of etching and polishing, as disclosed herein.

In FIG. 2F, the laser diode 108 then is bonded to mounting layer 106. Bonding the laser diode 108 may include, for example, solder bonding the laser diode 108 to the mounting layer 106 using a solder such as indium, AuSn, SACT, SACS, or Ag sinter, among others. A bottom surface of the laser diode 108 may include a diode contact, e.g., a p-type or n-type contact, such that soldering establishes a low resistance electrical pathway between the laser diode 108 and the mounting layer 106. The laser diode 108 may include, e.g., a semiconductor laser diode such as a gallium arsenide diode, indium phosphide diode, gallium antimonide diode, or gallium nitride diodes, among others.

An advantage of forming the insulating layer 104 over the raised features 202 in an interlocking pattern as disclosed herein is that, together with the main body portion 102 and the mounting layer 106, the laser diode cooler 100 may have an effective coefficient of thermal expansion that is lower than the coefficient of thermal expansion of the cooler 100 without the interlocking structures. The lower effective coefficient of thermal expansion thus reduces the internally generated stresses/forces caused by heating during operation of a laser diode. In particular, in some implementations, the thicknesses of the raised features 202 and the electrically insulating layer 104 can be designed so as to approximately match the effective coefficient of thermal expansion of the laser diode cooler 100 with the laser diode coefficient of thermal expansion. Without wishing to be constrained by theory, an effective overall coefficient of thermal expansion, αₒᵥᵣ, for a composite structure can be expressed as proportional to:

$${α}_{ovr} ∼ \frac{( {α}_{1} {t}_{1} + {α}_{2} {t}_{2} )}{T}$$

where α₁ is the coefficient of thermal expansion for a first material in the composite, az is the coefficient of thermal expansion for a second material in the composite, ti is the thickness of the first material in the composite, t₂ is the thickness of the second material in the composite, and T is the overall thickness of the composite. As an example, for a laser diode having a coefficient of thermal expansion in the range of about 5.5*10⁻⁶ to about 6.5*10⁻⁶/K, the thickness and distribution of the raised features (e.g., features 202 or 110), as well as the thickness of the electrically insulating layer 104, in the laser diode cooler 100 can be designed to provide an effective coefficient of thermal expansion that falls within that range, e.g., about 6*10⁻⁶/K.

The examples disclosed so far include interlocking structures formed at the interface between the main body portion 102 and the electrically insulating layer 104. Alternatively, or in addition, interlocking structures also may be formed at the interface between the electrically insulating layer 104 and the laser diode mounting layer 106. For example, FIG. 2G is a schematic that illustrates a side view of an example laser diode cooler 250 that includes a first set of interlocking structures formed using raised features 202 at the interface between layer 104 and main body portion 102, and a second set of interlocking structures formed using raised features 220 at the interface between layer 104 and mounting layer 106. Providing an additional set of interlocking structures can help further strengthen the adhesion of the insulating layer to both the main body portion 102 and the mounting layer 106. The features 220 may be formed, e.g., using a subtractive process, such as chemical etching, ion milling, or laser scribing. For example, in some implementations, the features 220 may be formed by using photolithography with a photosensitive resist to define certain areas of the electrical insulating layer 104 to etched using, e.g., a chemical etchant and other areas to be protected 200. Features 220 may have a height 225 defined by the thickness of material removed from the electrical insulating layer 104. The height 225 may be in the range about 100 nm to about 75 microns. For example, the height 225 may be greater than about 500 nm, greater than about 1 micron, greater than about 2 microns, greater than about 4 microns, greater than about 5 microns, greater than about 10 microns, greater than about 20 microns, greater than about 25 microns, greater than about 30 microns, greater than about 40 microns, or greater than about 50 microns. After forming the features 220 in the electrical insulating layer 104, the mounting layer 106 may be formed as described herein with respect to FIGS. 2D-2E using, e.g., an electrolytic process. During formation of the mounting layer 106, the mounting layer material fills in the openings or voids between features 220 to form the second set of interlocking structures.

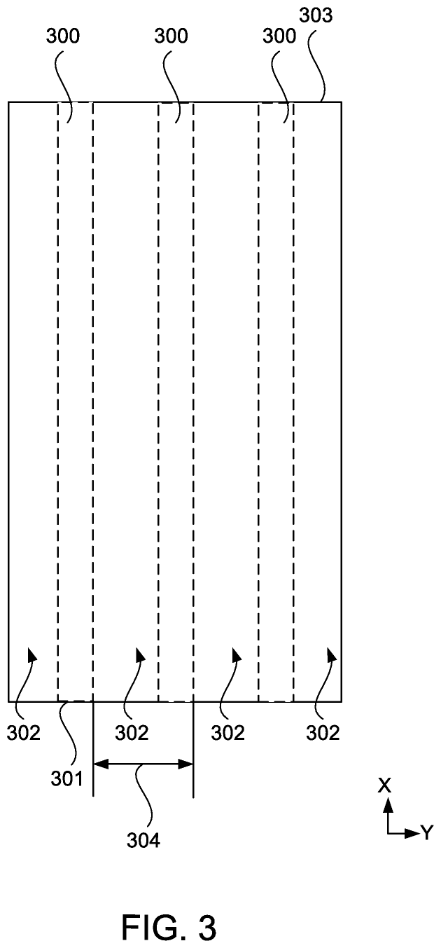

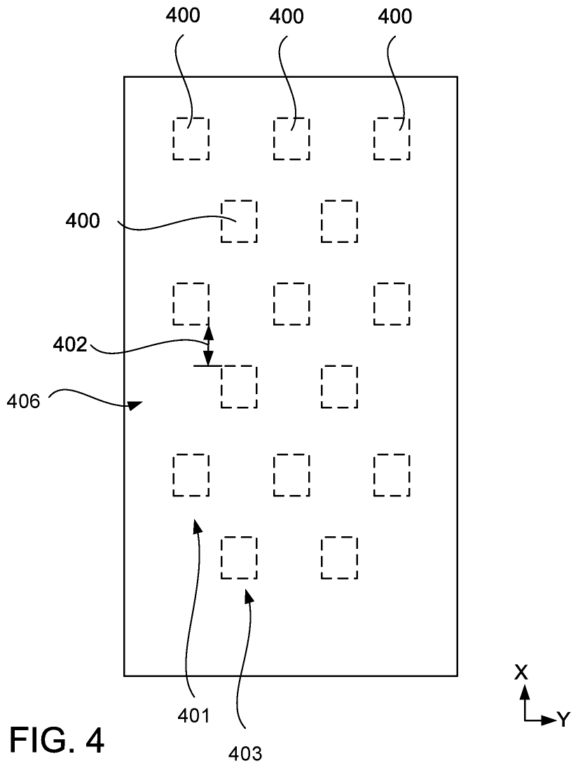

As disclosed herein, in some implementations, the interlocking structures are formed in a predetermined pattern. The predetermined pattern can include an ordered array of shapes. For example, the interlocking structures may include protrusions, ridges, nodules, or rings arranged in an array. FIG. 3 is a schematic that illustrates a top view of the principle surface of the main body portion 102 of a laser diode cooler prior to forming the electrically insulating layer 104. In the example of FIG. 3, the dashed lines represent the edges of raised features 300 (e.g., such as features 110 or 202), which are provided as elongated lines extending from a first edge 301 of the main body portion to a second opposite edge 303 of the main body portion. The regions 302 between features 300 are gaps or voids that are filled with the electrically insulating material. The features 300 are arranged in an array having a pitch 304. The width of the features 300 may be in the range of, e.g., about 1 micron to about 40 microns, such as 5 microns, 10 microns, 20 microns or 30 microns. The features 300 may have lengths that extend the entire length of the main body portion 102, or, e.g., only one quarter, one third, one half or three quarters the length of the main body portion 102. Other lengths are also possible. The pitch 304 may be in the range of, e.g., greater than or equal to about 1 micron and less than about 80 microns, such as about 2 microns or greater, about 5 microns or greater, about 10 microns or greater, about 20 microns or greater, about 30 microns or greater, about 40 microns or greater, about 50 microns or greater, about 60 microns or greater, or about 70 microns or greater. A distance between directly adjacent features 300 may be greater than about 0.5 microns and less than about 50 microns, such as about 1 micron or greater, about 5 microns or greater, about 10 microns or greater, about 20 microns or greater, about 30 microns or greater, or about 40 microns or greater.

FIG. 4 is a schematic illustrates a top view of the principle surface of the main body portion 102 of another example pattern of the interlocking structures. Features 400 defined by the region enclosed by the dashed lines may correspond to raised features (e.g., features 110 or 202), in which case region 406 corresponds to the area in which the electrically insulating film is to be formed. Alternatively, in other implementations, features 400 enclosed by the dashed lines define voids or openings in the main body portion into which the insulating layer is formed, in which case region 406 corresponds to a surface of the main body portion 102. The features 400 are shown as having a square footprint in this example, but may have any desired footprint including, e.g., circles, annular rings, or triangles. Although both FIG. 3 and FIG. 4 depict the features 400 as having sharp edges, it is possible to form the features 400 to have sloped edges, such as truncated prisms that gradually increase in thickness to the maximum feature thickness. The surface area of each feature 400, as viewed when facing the principle surface of the main body portion, may be in the range of about 0.25 μm² to about 1000 μm².

Referring to the example of FIG. 4, the features 400 may be arranged in an ordered array of multiple columns and rows. The pitch between directly adjacent features 400 may be in the range of, e.g., greater than or equal to about 1 micron and less than about 80 microns, such as about 2 microns or greater, about 5 microns or greater, about 10 microns or greater, about 20 microns or greater, about 30 microns or greater, about 40 microns or greater, about 50 microns or greater, about 60 microns or greater, or about 70 microns or greater. A distance between directly adjacent features 400 may be greater than about 0.5 microns and less than about 50 microns, such as about 1 micron or greater, about 5 microns or greater, about 10 microns or greater, about 20 microns or greater, about 30 microns or greater, or about 40 microns or greater.

In some implementations, each column (row) of features 400 is aligned to each directly adjacent column (row) of features 400 in the array. Alternatively, as shown in FIG. 4, directly adjacent columns (rows) may be offset from one another rather than have their features aligned along common rows (columns). For instance, in the example shown in FIG. 4, a first column 401 of features 400 is offset from an identical second column 403 of features by a first distance 402.

A number of embodiments have been described. Nevertheless, it will be understood that various modifications may be made without departing from the spirit and scope of the invention. Accordingly, other embodiments are within the scope of the following claims.

What is claimed is:

1. A laser diode heat sink comprising:
a main body portion formed of metal;
an electrically insulating layer on a principal surface of the main body portion, wherein an interface between the main body portion and the electrically insulating layer comprises a plurality of interlocking structures; and
a metal mounting layer for mounting a laser diode on the electrically insulating layer.

2. The laser diode heat sink of claim 1, wherein an effective coefficient of thermal expansion of the laser diode heat sink is approximately matched to a coefficient of thermal expansion of the laser diode.

3. The laser diode heat sink of claim 1, wherein an effective coefficient of thermal expansion of the laser diode heat sink is between about 5.5*10⁻⁶/K and about 6.5*10⁻⁶/K.

4. The laser diode heat sink of claim 1, wherein the plurality of interlocking structures comprises a plurality of protrusions arranged in a periodic array.

5. The laser diode heat sink of claim 4, wherein a pitch between adjacent protrusions in the periodic array is greater than about 1 micron.

6. The laser diode heat sink of claim 4, wherein a distance between adjacent protrusions in the periodic array is greater than about 0.5 micron.

7. The laser diode heat sink of claim 4, wherein the plurality of protrusions comprises a plurality of elongated ridges.

8. The laser diode heat sink of claim 4, wherein the plurality of protrusions comprises a plurality of nodules.

9. The laser diode heat sink of claim 4, wherein a thickness of the plurality of protrusions is between approximately 1 micron to approximately 50 microns.

10. The laser diode heat sink of claim 1, wherein a thickness of the electrical insulating layer is between approximately 1 micron and approximately 50 microns.

11. The laser diode heat sink of claim 1, wherein the electrical insulating layer comprises a diamond layer.

12. The laser diode heat sink of claim 1, wherein a thickness of the mounting layer is between approximately 100 microns to approximately 500 microns.

13. The laser diode heat sink of claim 1, wherein the plurality of interlocking structures comprises a plurality of depressions defined by the principal surface of the main body portion, and wherein the mounting layer fills the plurality of depressions.

14. The laser diode heat sink of claim 1, wherein the main body portion comprises a plurality of integrated fluid channels.

15. A method of manufacturing a laser diode heat sink, the method comprising:
providing a main body portion formed of metal;
forming a plurality of protrusions on or a plurality of openings in a principal surface of the main body portion;
forming an electrically insulating layer on the principal surface so as to cover the plurality of protrusions or to fill the plurality of openings and form interlocking structures with the plurality of protrusions or with the plurality of openings; and
forming a laser diode mounting layer on the electrically insulating layer.

16. The method of manufacturing the laser diode heat sink of claim 15, wherein forming the plurality of openings in the principal surface of the main body portion comprises performing at least one of mechanically milling, chemically etching or laser scribing predefined regions of the principal surface.

17. The method of manufacturing the laser diode heat sink of claim 15, wherein forming the plurality of protrusions on the principal surface of the main body portion comprises:
depositing a layer of metal on the principal surface to form a deposited metal layer; and
patterning the deposited metal layer to form the plurality of protrusions.

18. The method of manufacturing the laser diode heat sink of claim 15, wherein forming the electrically insulating layer comprises forming a diamond film on the principal surface.

19. The method of manufacturing the laser diode heat sink of claim 15, wherein forming the laser diode mounting layer comprises electroplating the laser diode mounting layer on the electrically insulating layer.

20. The method of manufacturing the laser diode heat sink of claim 15, wherein forming the laser diode mounting layer comprises soldering the laser diode mounting layer to the electrically insulating layer.
